(19) United States
(12) Patent Application Publication
(10) Pub. No.: US 2021/0163519 A1
(43) Pub. Date: Jun. 3, 2021

(54) BIS(ALKYLTETRAMETHYLCYCLOPENTADIENYL)ZINC, PRECURSOR FOR CHEMICAL VAPOR DEPOSITION, AND PRODUCTION METHOD FOR ZINC-CONTAINING THIN FILM

(71) Applicant: KOJUNDO CHEMICAL LABORATORY CO., LTD., Sakado-shi, Saitama (JP)

(72) Inventors: Nobutaka TAKAHASHI, Sakado-shi, Saitama (JP); Fumikazu MIZUTANI, Sakado-shi, Saitama (JP)

(73) Assignee: KOJUNDO CHEMICAL LABORATORY CO., LTD., Sakado-shi, Saitama (JP)

(21) Appl. No.: 17/265,856

(22) PCT Filed: Nov. 21, 2019
(86) PCT No.: PCT/JP2019/045581

§ 371 Date: Feb. 4, 2021

(30) Foreign Application Priority Data
Dec. 6, 2018 (JP) 2018-228705

(51) Int. Cl. C07F 17/00; C01G 9/03; C23C 16/455; C23C 16/40

(52) U.S. Cl. CPC C07F 17/00; C01G 9/03; H01L 21/28506; C23C 16/407; C23C 16/45553

(57) ABSTRACT

Provided is a precursor for chemical vapor deposition for depositing a zinc-containing thin film. Bis(alkyltetramethylcyclopentadienyl)zinc represented by the formula (1) which is liquid at room temperature and is therefore easy to handle (in the formula (1), R¹ and R² are alkyl group having 3 carbon atoms); a precursor for chemical vapor deposition comprising bis(alkyltetramethylcyclopentadienyl)zinc represented by the formula (2) (in the formula (2), R³ and R⁴ are alkyl group having 2-5 carbon atoms); and a production method for a zinc-containing thin film through chemical vapor deposition.

### TECHNICAL FIELD

The present invention relates to an organic zinc compound for chemical vapor deposition and a precursor for chemical vapor deposition.

### BACKGROUND ART

Transparent conductive films are used in many ways, such as flat panel displays, solar cells, touchscreens, heat ray reflective films, transparent heaters, transparent electromagnetic wave shields, and antistatic films owing to the useful characteristics. Materials used for the transparent conductive films are composed of zinc oxide doped with metallic elements such as aluminum, gallium, indium and boron, and halogen elements such as fluorine. They can be made into a conductive film at low temperature, and are excellent in electrical properties, optical properties, and resistance to hydrogen plasma, and therefore the zinc oxide-based films are most commonly used for transparent conductive films.

Zinc oxide-based thin films can be deposited by physical vapor deposition (PVD) such as sputtering, and chemical vapor deposition (CVD) such as atomic layer deposition (ALD). Among these, in the chemical vapor deposition, a precursor for chemical vapor deposition is supplied to a reaction chamber equipped with a substrate in a gaseous state, and then the precursor undergoes a thermal decomposition, a chemical reaction, a photochemical reaction, or the like on the substrate to deposit a thin film having a desired composition. For example, in the case of the thermal decomposition, the precursor for chemical vapor deposition is brought into contact with the substrate heated to a temperature higher than the thermal decomposition temperature of the precursor to deposit a metal film on the substrate. Therefore, the precursor for chemical vapor deposition must be able to vaporize at a temperature lower than the temperature of the substrate, and this precursor needs to have sufficiently high vapor pressure to deposit a uniform film on the substrate.

PTL 1 discloses zincocene and its derivative as a precursor for use in vapor deposition of zinc oxide-based thin film. According to PTL 1, a new precursor for chemical vapor deposition having excellent thermal and chemical stability and high vapor pressure, can deposit high purity zinc oxide-based thin films containing few impurities such as carbon, by varying the reactant gases and/or the condition such as the deposition temperatures.

However, because the compounds are solid at room temperature, they must be vaporized after being melted or be sublimed in the process of chemical vapor deposition. Therefore, the solid compounds need to be heated to about their melting point so as to change into a gaseous state. Furthermore, the temperature of a supply pipe to a reaction chamber and the temperature of the reaction chamber need to be kept at the temperature higher than the temperature of the precursor and below its thermal decomposition temperature, which makes the operation complicated.

### CITATION LIST

### Patent Literature

### PTL 1: JP2013-108178A

### SUMMARY OF INVENTION

### Technical Problem

An object of the present invention is to provide bis(alkyltetramethylcyclopentadienyl)zinc which is liquid at room temperature and is easy to handle, as a precursor for chemical vapor deposition for depositing a zinc-containing thin film.

### Solution to Problem

The present invention solves the foregoing problems in the prior art and comprises the following requirements.

Bis(alkyltetramethylcyclopentadienyl)zinc of the present invention is represented by the following formula (1).

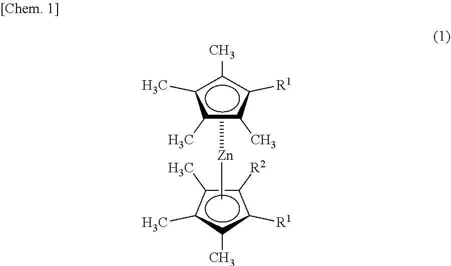

In the formula (1), R¹ and R² are alkyl group having 3 carbon atoms.

The precursor for chemical vapor deposition of the present invention comprises bis(alkyltetramethylcyclopentadienyl)zinc represented by the following formula (2) as a main component.

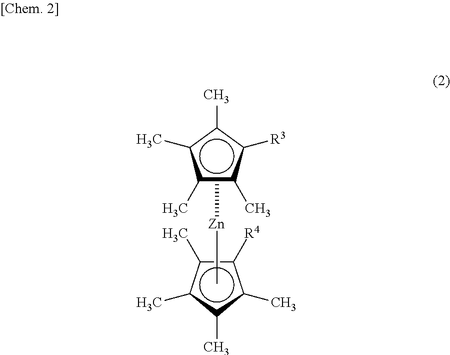

In the formula (2), R³ and R⁴ are alkyl group having 2 to 5 carbon atoms.

The precursor for chemical vapor deposition is preferably liquid at 23° C.

The production method for zinc-containing thin film of the present invention is carried out by chemical vapor deposition using a precursor being liquid at 23° C. where bis(alkyltetramethylcyclopentadienyl)zinc represented by the following formula (2) is contained as a main component.

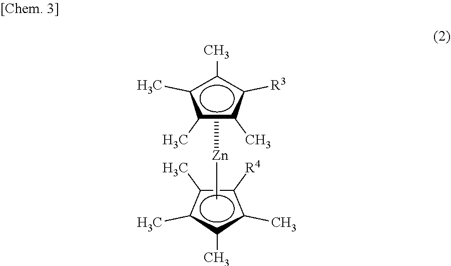

In the formula (2), R³ and R⁴ are alkyl group having 2 to 5 carbon atoms.

The chemical vapor deposition is preferably atomic layer deposition.

### Advantageous Effects of Invention

Bis(alkyltetramethylcyclopentadienyl)zinc represented by the formula (1) or (2) is suitable for a precursor for chemical vapor deposition because it is liquid at room temperature and easy to handle.

### DESCRIPTION OF EMBODIMENTS

Hereinafter, bis(alkyltetramethylcyclopentadienyl)zinc represented by the formula (1) of the present invention will be described.

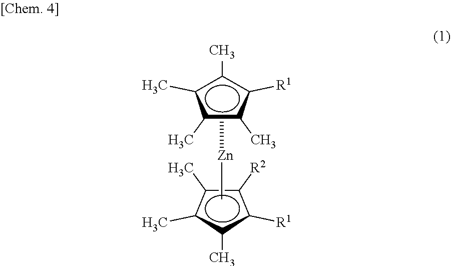

In the formula (1), R¹ and R² are alkyl group having 3 carbon atoms. R¹ and R² may be the same or different, but it is desirable that they are the same because of ease of synthesis.

The alkyl group having 3 carbon atoms includes n-propyl group and isopropyl group, and preferably n-propyl group.

Bis(alkyltetramethylcyclopentadienyl)zinc represented by the formula (1) is liquid at 23° C., atmospheric pressure, and has high vapor pressure. Therefore, it is suitable for a precursor for chemical vapor deposition.

The precursor for chemical vapor deposition of the present invention comprise bis(alkyltetramethylcyclopentadienyl)zinc represented by the formula (2) as a main component.

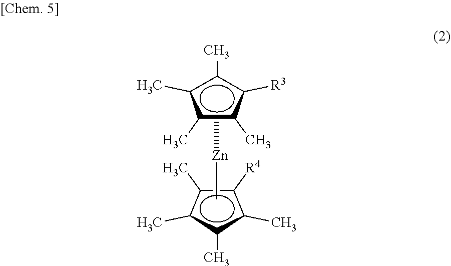

In the formula (2), R³ and R⁴ are alkyl group having 2 to 5 carbon atoms. R³ and R⁴ may be the same or different, but it is desirable that they are the same because of ease of synthesis.

The alkyl group having 2 to 5 carbon atoms includes ethyl group, n-propyl group, isopropyl group, n-butyl group, isobutyl group, sec-butyl group, tert-butyl group, neopentyl group, 3-methylbutyl group, 1-methylbutyl group, 1-ethylpropyl group, and 1,1-dimethylpropyl group.

Among these, R³ and R⁴ are preferably alkyl groups each having 3 to 5 carbon atoms. To be specific, n-propyl group, isopropyl group, n-butyl group, isobutyl group, sec-butyl group, and tert-butyl group are preferable; n-propyl group and isopropyl group are more preferable; and n-propyl group is particularly preferable.

It is desirable that bis(alkyltetramethylcyclopentadienyl)zinc represented by the formula (1) or (2) be liquid at room temperature. Therefore its melting point is preferably below room temperature, specifically below 35° C., more preferably below 23° C., further preferably below 20° C., and particularly preferably below 10° C.

The content of bis(alkyltetramethylcyclopentadienyl)zinc represented by the formula (2) in the precursor for chemical vapor deposition is desirably almost 100%, but a very small amount of impurities are allowed to be contained as long as they neither react on bis(alkyltetramethylcyclopentadienyl)zinc nor vaporize at a temperature when bis(alkyltetramethylcyclopentadienyl)zinc is used as the precursor for vapor deposition.

By the chemical vapor deposition (CVD), a thin film is deposited using bis(alkyltetramethylcyclopentadienyl)zinc represented by the formula (1), or the precursor for chemical vapor deposition comprising bis(alkyltetramethylcyclopentadienyl)zinc represented by the formula (2) as a main component, according to the present invention. In the chemical vapor deposition, the container of the precursor filled with bis(alkyltetramethylcyclopentadienyl)zinc is heated up to vaporization, and the vapor is supplied to the reaction chamber. In order to supply the precursor, namely, bis(alkyltetramethylcyclopentadienyl)zinc to the substrate in the reaction chamber, the temperature of a supply pipe that connects the precursor container with a reaction chamber and the reaction chamber needs to be set at a temperature where the precursor does not thermally decompose but maintains a gaseous state; in other words, a temperature that is higher than the temperature of the precursor container (i.e., the vaporization temperature of the precursor) and lower than the thermal decomposition temperature of the precursor. To enlarge the range of temperature for film deposition, i.e., the substrate temperature, it is desirable that the temperature of the precursor container be as low as possible and that the precursor used have sufficiently high vapor pressure even at low temperature.

The chemical vapor deposition includes thermal CVD in which deposition is formed by the continuous thermal decomposition on the substrate, and atomic layer deposition (ALD) in which individual atomic layers are deposited one layer at a time; and among them, atomic layer deposition (ALD) is preferable. For example, in an ALD, alternatively supplying bis(alkyltetramethylcyclopentadienyl)zinc as the precursor and an oxidant, and allowing them to react on the surface of the substrate, the zinc oxide-based thin film defined by an atomic layer scale can be deposited. The oxidant includes water vapor, ozone, and plasma-activated oxygen.

Bis(alkyltetramethylcyclopentadienyl)zinc of the present invention is liquid at room temperature, which enables the rate of precursor gas supply to be precisely controlled with a flow rate controller.

In case the precursor for vapor deposition is solid at room temperature, it becomes harder to adjust the rate of precursor supply with a flow rate controller. As a result, the rate of supplying the precursor to the reaction chamber fails to be controlled easily and precisely.

### EXAMPLES

Hereinafter, the present invention will be described in detail with reference to examples, but the present invention is not restricted to the examples.

### Example 1

To a 1 L four-necked flask, 400 ml of THF, 14.4 g (0.37 mol) of potassium metal, and 142.2 g (0.87 mol) of C₅(CH₃)₄(n-C₃H₇)H were added, and the mixture was allowed to react for 52 hours. THF was distilled off at 100° c. under reduced pressure to obtain C₅(CH₃)₄(n-C₃H₇)K.

To the C₅(CH₃)₄(n-C₃H₇)K, 600 ml of THF and 24.7 g (0.18 mol) of ZnCl₂ were added, and the mixture was stirred at 50° C. for 5.5 hours. By distilling off THF at 50° c. under reduced pressure, solid content was obtained.

Distilling the solid content twice using a simple distillation apparatus at 100-150° C. and at 0.4-0.5 torr gave 37.6 g (0.096 mol) of yellow liquid in 53.3% yield (based on ZnCl₂).

Analysis through the following (1) to (3) proved the obtained sample to be Zn[C₅(CH₃)₄(n-C₃H₇)]₂.

### (1) Composition Analysis

ICP atomic emission spectrophotometry of the liquid obtained by wet decomposition of the sample showed that the Zn content was 15.9% (theoretical value: 16.7%).

### (2) ¹H-NMR

Measurement condition: 400 MHz Varian UNITY INOVA-400S spectrometer; THF-d8 solvent; and 1D method

1.87 (12H, singlet) ppm: C₅(CH₃)₄, 1.84 (12H, singlet) ppm: C₅(CH₃)₄, 2.23-2.19 (4H, multiplet) ppm: CH₂CH₂CH₃, 1.24-1.19 (4H, sextet) ppm, CH₂CH₂CH₃, 0.98-0.84 (6H, triplet) ppm: CH₂CH₂CH₃

### (3) ¹³C-NMR

Measurement condition: 100 MHz Varian UNITY INOVA-400S spectrometer; THF-d8 solvent; and 1D method

114.01, 113.28, 109.79 ppm: C5,

29.13, 25.89, 14.37, 10.99, 10.84 ppm: C(CH₃)₄(n-C₃H₇)

Next, sealed cell differential scanning calorimetry (SC-DSC) at a heating rate of 10° C./min showed that the compound has a melting point of approximately 5° C. and does not thermally decompose until the temperature reaches approximately 250° C. The vaporization rate calculated from weight change at 150° C. in 1 atm argon atmosphere was approximately 50 μg/min.

Accordingly, Zn[C₅(CH₃)₄(n-C₃H₇)]₂ being liquid at room temperature certainly has thermal stability and vaporizability indispensable for chemical vapor deposition.

### Comparative Example 1

To a 1 L four-necked flask, 400 ml of THF, 11.6 g (0.30 mol) of potassium metal and 42.1 g (0.45 mol) of C₅H₄(C₂H₅)H were added, and the mixture was allowed to react for 21 hours. THF was distilled off at 40° c. under reduced pressure to obtain C₅H₄(C₂H₅)K.

To the C₅H₄(C₂H₅)K, 600 ml of THF and 19.4 g (0.14 mol) of ZnCl₂ were added at −78° c., and the mixture was stirred at 50° C. for 6 hours. By distilling off THF at 50° c. under reduced pressure, solid content was obtained.

Distilling the solid content twice using a simple distillation apparatus at 120-190° C. and at 0.4-0.5 torr gave 8.1 g (0.032 mol) of pale yellow solid in 22.9% yield (based on ZnCl₂).

Analysis through the following (1) to (3) proved the obtained sample to be Zn[C₅H₄(C₂H₅)]₂.

### (1) Composition Analysis

ICP atomic emission spectrophotometry of the liquid obtained by wet decomposition of the sample showed that the Zn content was 25.7% (theoretical value: 26.0%).

### (2) ¹H-NMR

Measurement condition: 400 MHz Varian UNITY INOVA-400S spectrometer; THF-d8 solvent; and 1D method 5.72-5.71 (4H, doublet) ppm: C₅H₄, 5.35-5.34 (4H, doublet) ppm: C₅H₄, 2.57-2.51 (4H, quartet) ppm: CH₂CH₃, 1.23-1.19 (6H, triplet) ppm: CH₂CH₃

### (3) ¹³C-NMR

Measurement condition: 100 MHz Varian UNITY INOVA-400S spectrometer; THF-d8 solvent; and 1D method

138.50, 138.18, 109.51, 109.49, 99.28, 99.27 ppm: C5,

23.67, 15.81 ppm: CH₂CH₃

Next, sealed cell differential scanning calorimetry (SC-DSC) at a heating rate of 10° C./min showed that the compound has a melting point of approximately 90° C. and thermal decomposition starts at approximately 184° C. The vaporization rate calculated from weight change at 150° C. in 1 atm argon atmosphere was approximately 0.7 μg/min.

Accordingly, Zn[C₅H₄(C₂H₅)]₂ being solid at room temperature is inferior to the compound of the present invention in both thermal stability and vaporizability.

1. Bis(alkyltetramethylcyclopentadienyl)zinc represented by the following formula (1): 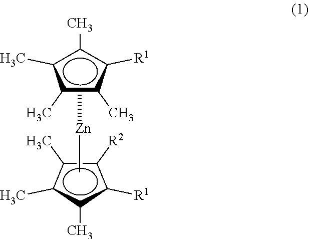
in the formula (1), R¹ and R² are alkyl group having 3 carbon atoms.

2. A precursor for chemical vapor deposition comprising bis(alkyltetramethylcyclopentadienyl)zinc represented by the following formula (2) as a main component: 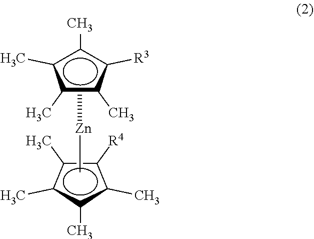
in the formula (2), R³ and R⁴ are alkyl group having 2 to 5 carbon atoms.

3. The precursor for chemical vapor deposition according to claim 2, being liquid at 23° C.

4. A production method for zinc-containing thin film by chemical vapor deposition using a precursor which is liquid at 23° C. for chemical vapor deposition comprising bis(alkyltetramethylcyclopentadienyl)zinc represented by the following formula (2) as a main component: 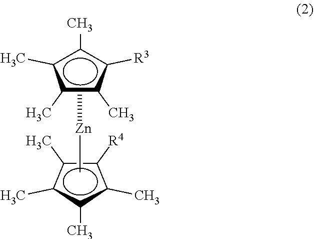
in the formula (2), R³ and R⁴ are alkyl group having 2 to 5 carbon atoms.

5. The production method for zinc-containing thin film according to claim 4, wherein the chemical vapor deposition is atomic layer deposition.
